(19) United States
(12) Patent Application Publication
(10) Pub. No.: US 2024/0379838 A1
(43) Pub. Date: Nov. 14, 2024

(54) VERTICAL MOSFET USING A SILICON CARBIDE LAYER AND A SILICON LAYER FOR IMPROVED PERFORMANCE

(71) Applicant: MaxPower Semiconductor, Inc., San Jose, CA (US)

(72) Inventors: Mohamed Darwish, Campbell, CA (US); Jun Zeng, Torrence, CA (US)

(73) Assignee: MaxPower Semiconductor, Inc., San Jose, CA (US)

(21) Appl. No.: 18/658,910

(22) Filed: May 8, 2024

Related U.S. Application Data
(60) Provisional application No. 63/465,084, filed on May 9, 2023.
(60) Provisional application No. 63/468,781, filed on May 24, 2023.

(51) Int. Cl. H01L 29/78; H01L 29/06; H01L 29/16; H01L 29/66

(52) U.S. Cl. CPC H01L 29/7813; H01L 29/0607; H01L 29/1608; H01L 29/66734

(57) ABSTRACT

A vertical MOSFET has an N-type SiC drift layer connected to a drain electrode. An overlying Si layer creates an n-N heterojunction at the top of the SiC drift layer. A P-well layer and N+ source regions are formed in the Si layer. Trenched gates are formed in the Si layer that invert the P-well to create a conductive path between the Si source regions and the SiC drift region. JFET channel regions and gate regions are formed in the SiC layer for improving reliability of the MOSFET under reverse voltage conditions and under short circuit conditions. The SiC drift layer results in a higher breakdown voltage, lower on-resistance, and improved thermal conductivity, and the upper Si layer retains its higher channel mobility and stability and high gate drive efficiency.

### CROSS-REFERENCE TO RELATED APPLICATIONS

This application claims priority to provisional application Ser. No. 63/465,084, having a filing date of May 9, 2023, by Mohamed Darwish et al., and also claims priority to provisional application Ser. No. 63/468,781, having a filing date of May 25, 2023, by Mohamed Darwish et al.

### FIELD OF THE INVENTION

This invention relates to vertical power MOSFETs and, in particular, to such power MOSFETs having SiC and Si layers.

### BACKGROUND

Power MOSFETs are widely used as switching devices in many electronic applications. It is desirable that power MOSFETs have both low power losses and high reliability.

FIG. 1 is a cross-section of one type of conventional MOSFET 10 formed of silicon.

Over an N+ substrate 12 is grown an N-epitaxial drift layer 14. A P-type well 16 is then formed by ion implantation and thermal anneal or drive-in. N+ source regions 18 and P+ contact regions 20 are also formed by implantation and drive-in. A trenched gate 22 is then formed. The gate 22 has a gate oxide layer 24, and the etched trench is filled with doped polysilicon 26. An insulation layer 28 is formed over the gate 22. A metal source electrode 30 and a metal drain electrode 32 are then formed.

Similar trench MOSFETs structures, but using wide-bandgap semiconductor materials, such as silicon-carbide (SiC), offer several advantages over those that use silicon. Such advantages include higher breakdown voltage, lower on-resistance, and higher thermal conductivity.

However, the existence of carbon at the gate oxide interface in such SiC MOSFETs results in a lower channel mobility, which increases the channel resistance, and adversely affects the gate oxide stability and reliability. The low channel mobility necessitates the use of a higher gate-to-source voltage to drive the MOSFET in the on-state. For example, to fully turn on a SiC MOSFET, typically 15V-20V is needed versus 5V-10V in the case of silicon power MOSFETs. Furthermore, a negative gate bias may be need to turn-off the SiC MOSFET, which requires modification of existing drivers designed for silicon MOSFETs.

FIG. 2 illustrates the MOSFET of FIG. 1 but with the silicon drift layer 14 and silicon substrate 12 replaced with a SiC drift layer 34 and a SiC substrate 36. The SiC drift layer 34 and SiC substrate 36 result in a higher breakdown voltage, lower on-resistance, and improved thermal conductivity, and the upper Si layer retains its higher channel mobility and stability and high gate drive efficiency. However, the MOSFET of FIG. 2 has an inherent PN heterojunction that results in an undesirable voltage drop across it in the on-state and a high leakage current at reverse bias. Furthermore, the overlap of the gate oxide and the PN heterojunction will adversely affect the gate oxide quality. Therefore, such SiC/Si MOSFETs are not practical.

What is needed is a vertical power MOSFET that has the benefits of the SiC and Si layers without the drawbacks described above.

### SUMMARY

New trench MOSFET structures and their method of fabrication are disclosed. The MOSFETs are constructed of parallel stripes or cells with an array of identical cells being connected in parallel. Therefore, only a single cell needs to be described in detail.

In one embodiment, a MOSFET cell with one or more trench gates utilizes a narrow bandgap Si top layer over a wider bandgap SiC layer, where the heterojunction is n-N rather than P—N. The bottom N+ substrate layer can be formed of SiC or a polycrystalline SiC (PolySiC) material. This structure provides the advantages of higher breakdown voltage, lower specific on-resistance, higher thermal conductivity, higher reliability carbon-free gate oxide and ease of gate drive.

The top Si epitaxial layer is doped with an N-type dopant and includes one or more trench gate electrodes of a conductive material, such as doped polysilicon. The gate electrodes are surrounded by a dielectric material, such as silicon dioxide (SiO₂), formed completely within the Si epitaxial layer.

N+ source regions, a P-type P-well (body), and P+ contact regions (connected to the source metal) are all formed in the silicon.

The “lower” SiC layer includes a middle portion that forms a long-channel JFET, which includes P-type JFET gate regions separated by N-type JFET channel regions. The channel regions are below the gate trenches (formed in the silicon layer). The gate trench has a depth that is less than the top of the P-type JFET gate regions.

The P-type JFET gate regions are connected together and are connected to the source metal at certain locations via a P+ contact region. There may be a connection to the source metal at distributed locations in the cell array.

Under reverse bias, the voltage drops substantially across the SiC JFET and SiC drift region and only a small voltage drop occurs across the top Si MOSFET portion. This allows forming a high density of trench gates with short MOSFET channel length (<0.25 μm), which results in a lower specific on-resistance. A lower leakage current at reverse bias results because most of the voltage drop occurs across the JFET and drift region, and only a small portion of the total voltage drop occurs across the n-N heterojunction formed at the Si/SiC layers interface.

Furthermore, the JFET N-type channel regions pinch off during short circuit high current conditions to limit drain current.

In addition, at reverse bias, the JFET gate regions shield the gate trench bottom and protects the gate oxide by reducing the electric field.

To turn the device on, a positive bias is applied to the gate trench electrode, the P-channel is inverted, and an electron accumulation layer is created at the gate trench bottom portion. The electron current flows generally vertically from the N+ source, through the inverted P-channel, through the JFET channel, through the drift region, and through the SiC substrate.

Other semiconductor materials with narrower band-gap other than Si and wider band-gap other than SiC may be used that have similar characteristics.

The trench gate structure may instead be planar rather than trenched.

Various other embodiments are described using the Si/SiC layered structure.

### BRIEF DESCRIPTION OF DRAWINGS

FIG. 1 is a cross-section of a single cell in a conventional silicon, vertical MOSFET.

FIG. 2 illustrates an impractical MOSFET similar to FIG. 1 but with the drift region and substrate being SiC.

FIG. 3a illustrates one embodiment of the invention, where gate trenches are completely formed in an Si epitaxial layer grown over SiC, and where JFETs are formed in the SiC material at the N-N heterojunction interface of the Si and SiC.

FIG. 3b illustrates the use of planar gates instead of trenched gates.

FIG. 4a is similar to FIG. 3a but with the addition of a thin, heavily doped N-type layer at the n-N Si/SiC junction.

FIG. 4b is similar to FIG. 4a but with the gate trenches offset from the centers of the JFET channels to enable a higher density of gate trenches.

FIG. 4c is similar to FIG. 4a but with an additional highly doped N-type layer formed at and beyond the Si/SiC interface.

FIG. 5 is similar to FIG. 4a but with a thicker gate oxide at the bottom of the trenches.

FIG. 6 illustrates an area of a MOSFET cell showing how the JFET gates are shorted to the source metal by a P+ contact region extending between the source metal and the top of the JFET gate. The P+ contact region is formed around trenches that are not gate trenches. All JFET gates are connected together outside the plane of the figure.

FIG. 7 is similar to FIG. 6 but shows how any number of trench gates can be surrounded by the P+ contact region for the JFET gates.

FIG. 8 illustrates how the JFET gates can be connected to the source metal by a conducting material inside a trench contact that has sides covered by insulating material such silicon dioxide.

FIG. 9a illustrates how the vertical MOSFET can be only a portion of a die, where any other components can be formed in the Si.

FIG. 9b is similar to FIG. 9a but shows a P-type buried layer for insulating the N-type Si layer in the MOSFET from the N-type Si layer used for other components.

FIG. 10a is similar to FIG. 4a but with a Schottky diode to conduct a reverse current in the event of a reverse bias condition.

FIG. 10b illustrates the formation of a PN diode between two gate trenches to conduct a reverse current in the event of a reverse bias condition.

FIG. 11a illustrates a top-down view of strips of cells (containing gate trenches) surrounded by the deep P+ contact region of FIG. 6a (for shorting the JFET gates to the source metal) and showing locations of the JFET gates between the strips of gate trenches.

FIG. 11b illustrates a top-down view of rectangular cells (containing gate trenches) surrounded by the deep P+ contact region of FIG. 6a (for shorting the JFET gates to the source metal) and showing locations of the JFET gates between the rectangular gate trenches.

FIGS. 12a-12g illustrate process steps for forming the MOSFET embodiment of FIG. 7 or FIG. 8, which are easily adaptable to forming any of the other embodiments.

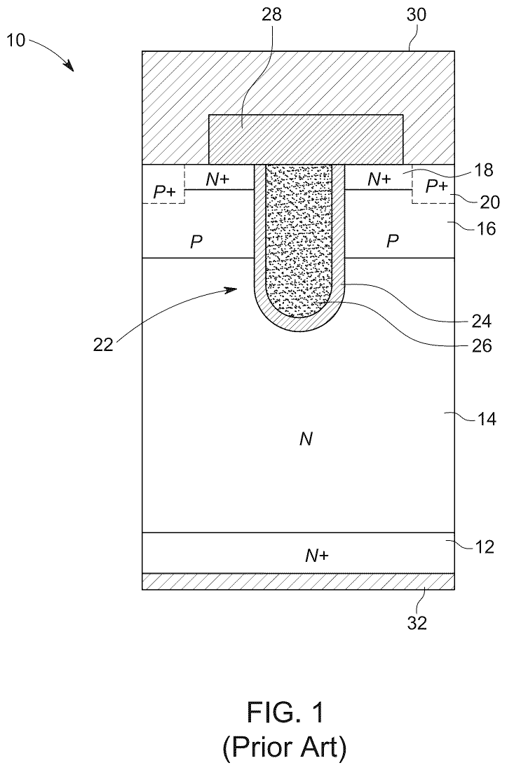

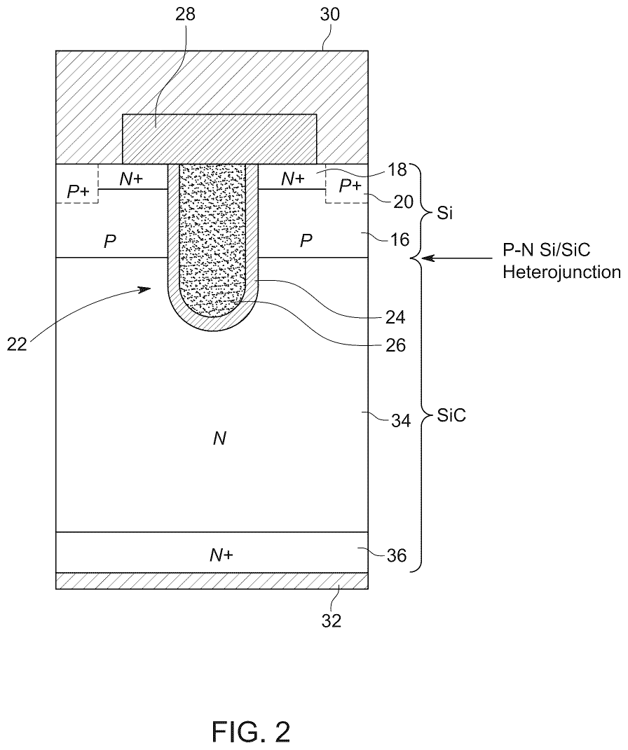

Elements labeled with the same numerals in the various figures may be the same or similar.

### DETAILED DESCRIPTION

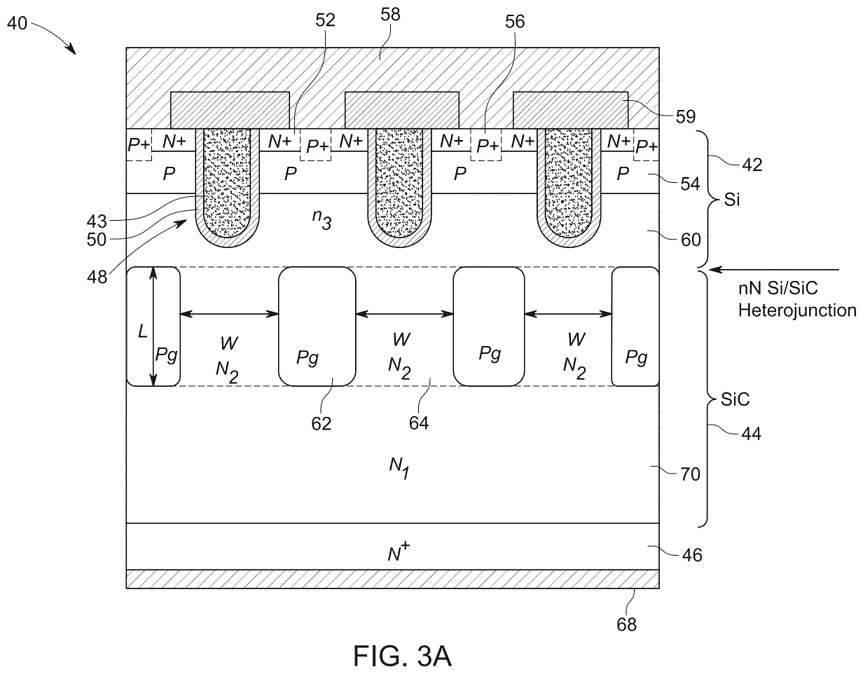

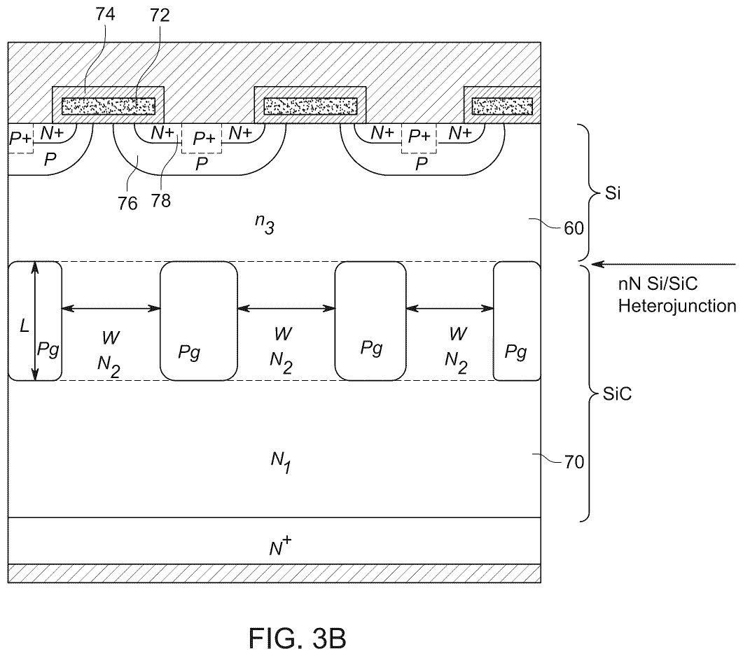

FIG. 3a illustrates one embodiment of the invention. Only a small portion of the full MOSFET is shown, where the portion is repeated over a die area.

The MOSFET cell 40 utilizes a relatively narrow bandgap semiconductor top layer, such as a Si layer 42, epitaxially grown over a wider bandgap semiconductor bottom layer, such as a SiC layer 44. Alternatively, the Si layer 42 is bonded to the SiC layer 44 by wafer bonding.

The bottom N+ substrate 46 can be formed of SiC or polycrystalline SiC (PolySiC) material. In an alternate embodiment, the substrate 46 can be Si, which is less expensive. The bottom of the substrate 46 is typically ground down. The structure of FIG. 3a provides the advantages of higher breakdown voltage, lower specific on-resistance, higher thermal conductivity, higher reliability carbon free gate oxide, and ease of gate drive.

The top epitaxial Si layer 42 is doped with an N-type dopant to have a dopant concentration of n3. The Si layer 42 includes one or more gate trenches 48 containing a gate electrode 43 of a conductive material, such as doped polysilicon. The gate electrodes 43 are surrounded by dielectric material, such as silicon dioxide (oxide) 50.

Formed in the Si layer 42 are N+ source regions 52, a P-type P-well (body) 54, and P+ contact regions 56 connected to the source metal 58 (source electrode). The bottom portion 60 of the Si layer 42 remains N-type. A dielectric 59 insulates the polysilicon from the source metal 58.

The SiC layer 44 is epitaxially grown over the substrate 46 to have an N-type dopant concentration of N1. The SiC layer 44 includes a long channel JFET with P-type JFET gates (Pg) 62 and JFET channels 64 having an N-type dopant concentration of N2. The channels 64 have a width W. The JFET gates 62 are connected to the source metal 58 in some locations in the die that are out of the plane of FIG. 3a. Under a reverse bias condition, where the source metal 58 and the gate electrode 43 are at ground potential (0V) and a positive voltage is applied to the drain metal 68, the voltage drops substantially across the JFET and drift region 70, and only a small voltage drop occurs across the Si layer 42. This allows forming a high density of trench gates with short MOS channel length (<0.25 μm), which results in a lower specific on-resistance. A lower leakage current under reverse bias results because most of the voltage drop occurs across the JFET and drift region 70, and only a small portion of the total voltage drop occurs across the n-N heterojunction formed at the Si/SiC layers interface of the Si N-type bottom portion 60 and the SiC JFET channels 64. In addition, at reverse bias, the JFET gates 62 shield the gate trench bottom and protect the gate oxide 50 by reducing the electric field.

Further, the JFET N-type channel regions 64 pinch off during short circuit high current conditions to limit drain current.

To turn the device on, when the source metal 58 is at ground potential and the drain metal 68 is positively biased, a positive bias is applied to the gate electrode 43 above a threshold voltage. As a result, the P-well 42 adjacent to the gate trenches is inverted (forming a channel), and an electron accumulation layer is created at the gate trench bottom portion. The electron current flows generally vertically from the N+ source regions 52, through the inverted channel, through the electron accumulation layer surrounding the bottom of the gate trench, through the bottom portion 60 of the Si layer 42, through the JFET channels 54, through the drift region 70, and through the drain metal 68 (drain electrode).

Other semiconductor materials may be used as long as the top layer has a bandgap that is narrower than the bottom layer and the heterojunction is n-N.

FIG. 3b shows a MOSFET structure similar to that shown in FIG. 3a but utilizes a planar gate structure instead of the trench gate. In FIG. 3b, horizontal polysilicon gates 72 are insulated by a dielectric 74 and invert a channel in P-body regions 76 to create a current path between the N+ source regions 78 and the Si bottom portion 60. The remainer is the same as FIG. 3a.

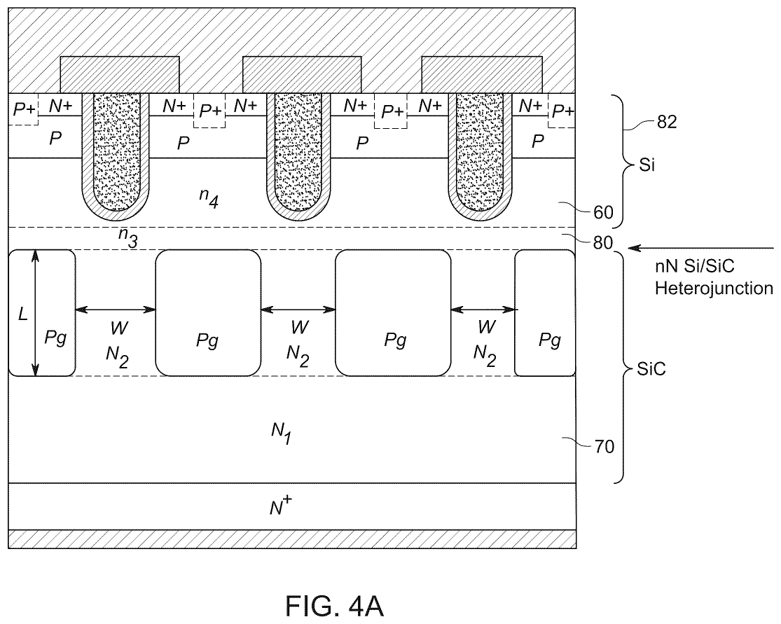

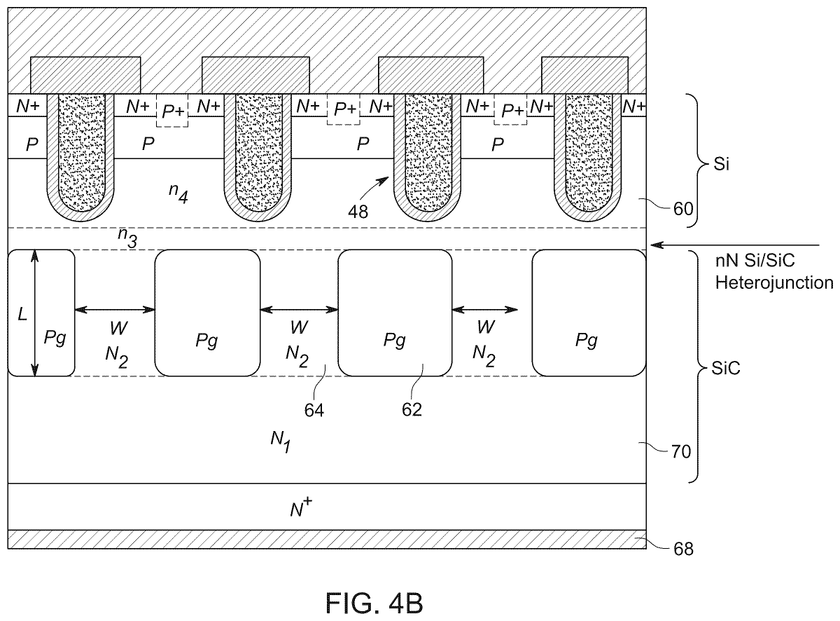

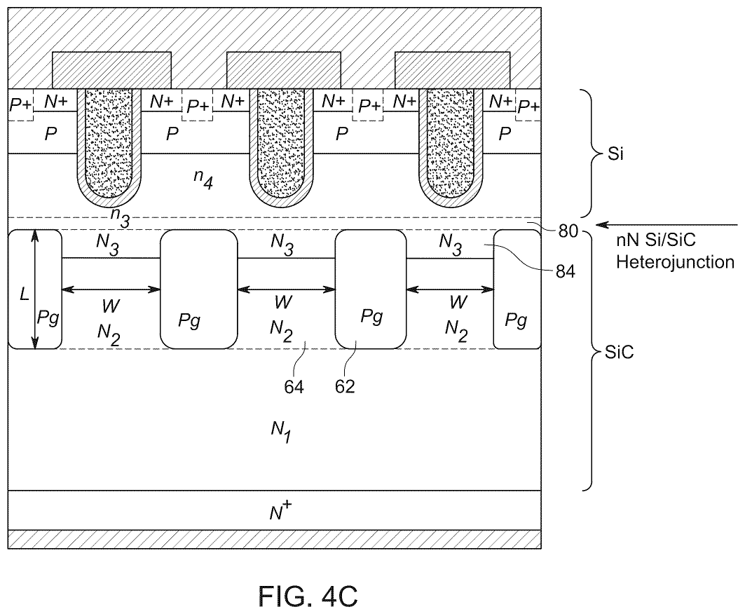

FIG. 4a shows a MOSFET structure is similar to that shown in FIG. 3a but with a heterojunction interface region 80 being heavily doped, with an N-type dopant concentration of n3, to provide thermionic current conduction across the n-N heterojunction and minimize the voltage across the interface. The portion of the Si layer 82 above the interface region 80 has a lower dopant concentration of n4. The interface region 80 transitions between the SiC crystal structure and the Si crystal structure.

FIG. 4b shows a MOSFET structure similar to that shown in FIG. 4a but with the number of gate trenches 48 (or gate electrodes 43) higher than the number of JFET channels 64, which increases current density and lowers the on-resistance. The gate trenches and JFET channels 64 are not necessarily aligned as the current flows generally vertically through the various channels and N-type regions to the drain metal 68. This allows increasing the density of gate trenches in the top layer independently from the JFET design.

FIG. 4c shows a MOSFET structure similar to that shown in FIG. 4a but the top of the JFET channel region 84 has an N-type doping concentration N3 that is higher than the remaining JFET channel region 64.

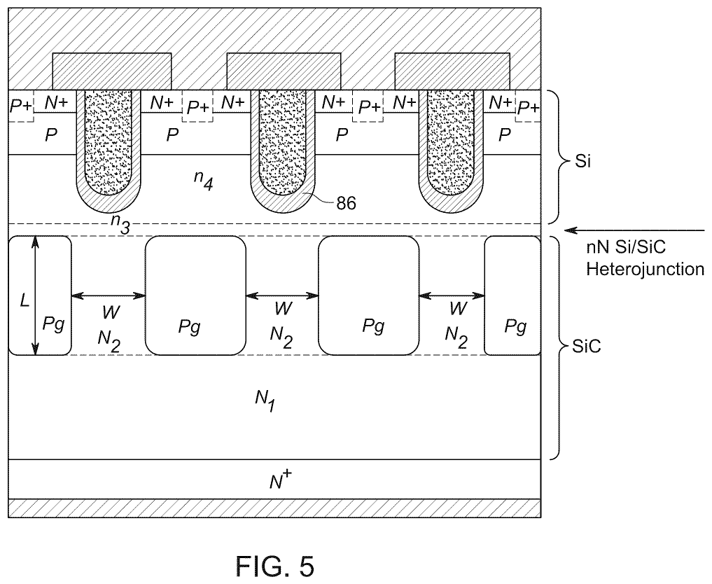

FIG. 5 is similar to FIG. 4a but with the trench gate oxide 86 being thicker at the trench bottom than the trench sidewalls. This feature provides lower electric field at the corners and bottom of the trench in addition to lower gate-drain capacitance.

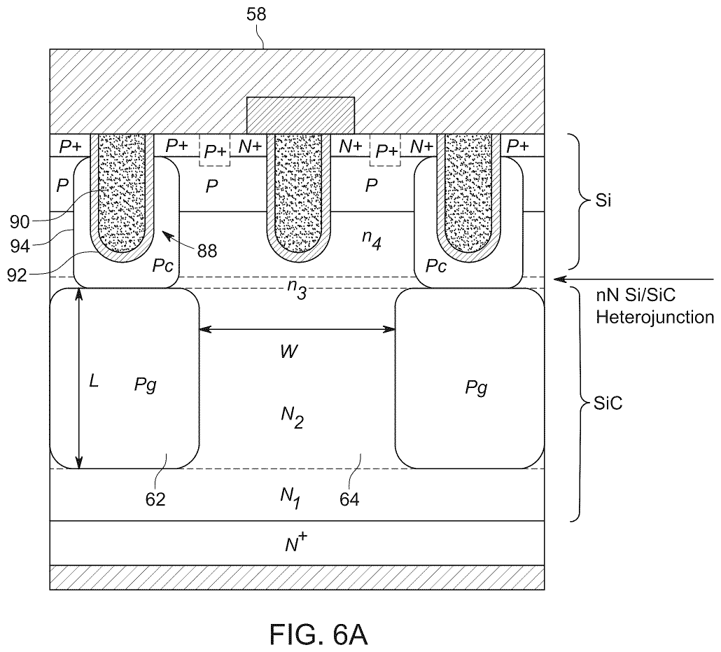

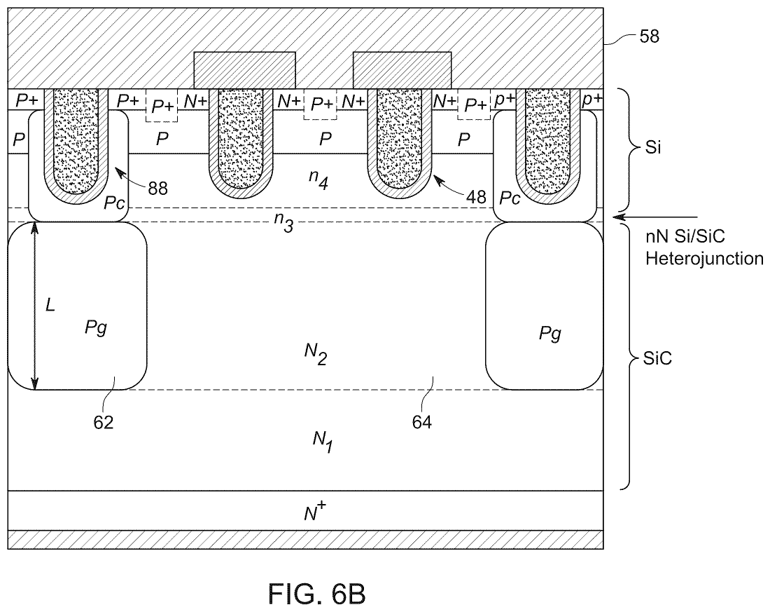

FIG. 6a illustrates how, in some areas, the JFET gates 62 are electrically connected to the source metal 58. A second type of trench 88 is formed that does not perform a gate function. The trench 88 is formed at the same time as the gate trenches and contains doped polysilicon, electrically connected to the source metal 58. The trench 88 is surrounded by a dielectric material 92 and a highly doped P-type contact region (Pc) 94 that connects the JFET gates 62 to the source metal 58. This results in all of the JFET gates 62 being biased by the source metal voltage since the JFET gates 62 form a continuous heavily doped region.

FIG. 6b is similar to FIG. 6a but the number of gate electrodes 48 (or gate trenches) is higher than the number of trenches 88 that are used to connect the JFET gates 62 to the source metal 58. This structure has the advantages of increasing the gate trench cell density plus a tolerant alignment requirement between the gate trenches and JFET channels.

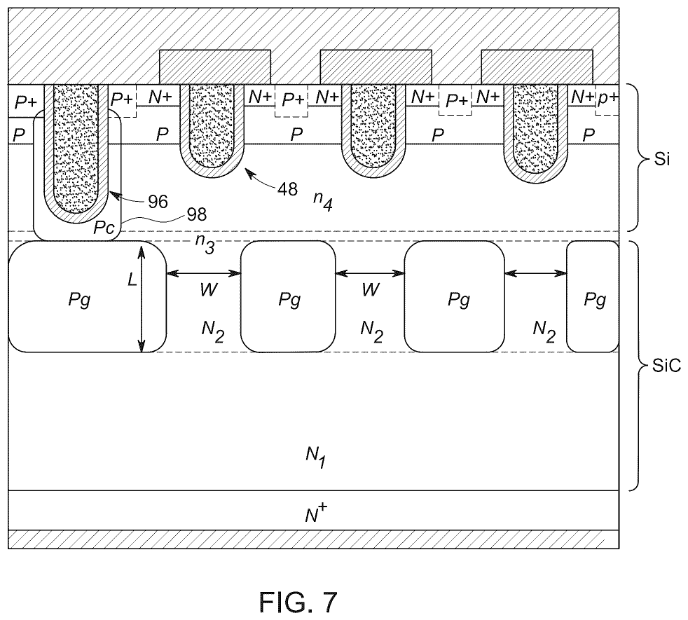

FIG. 7 is similar to FIG. 6b but with the trench 96 deeper than the trenches for the gate trench 48. The P+ contact region 98 is doped through the trench 96 before the trench 96 is filled with the polysilicon.

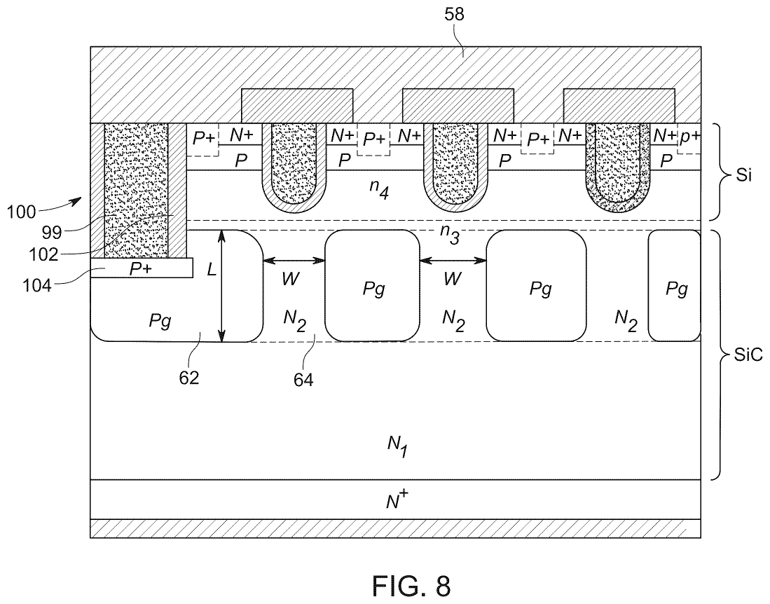

FIG. 8 is similar to FIG. 7 but with a trench 100 filled with a conducting material 99, such as tungsten or other suitable metal, that is connected between the source metal 58 and the JFET gates 62. A dielectric 102 insulates the conducting material 99. A P+ contact region 104 creates an ohmic contact between the conducting material 99 and the JFET gate 62.

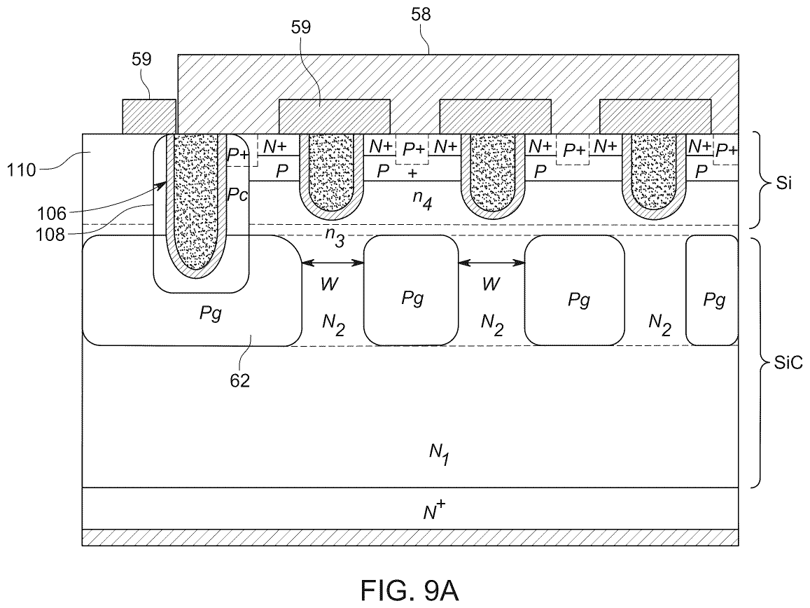

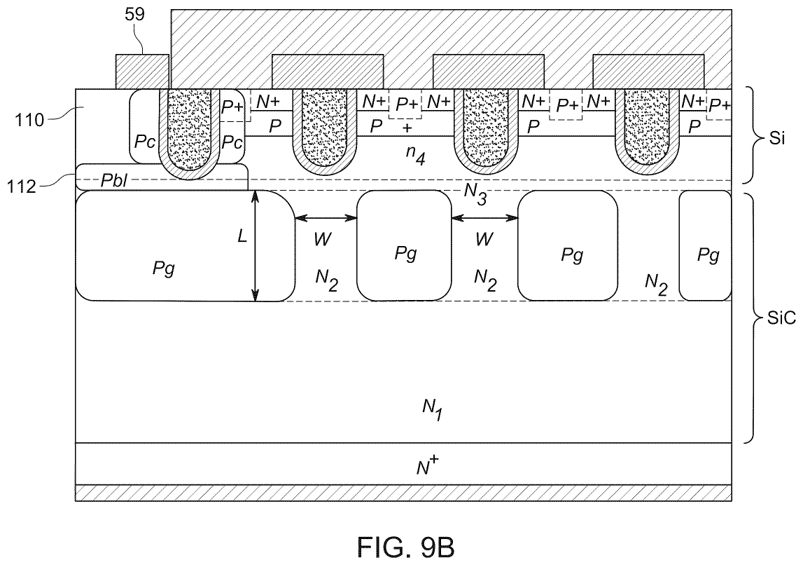

FIG. 9a shows how the trench 106, the P+ contact region 108, and the leftmost P-type JFET gate 62 form an isolated top Si island 110 that can be used to implement an Integrated Circuit (IC) that includes components such as CMOS, BJTs, and passive circuit components. This allows adding integrated component functionality to the discrete MOSFET device, such as drivers, over-voltage or over-temperature protection, etc.

FIG. 9b is similar to FIG. 9a but with an additional P-type buried layer (Pbl) 112 to isolate the Si island 110.

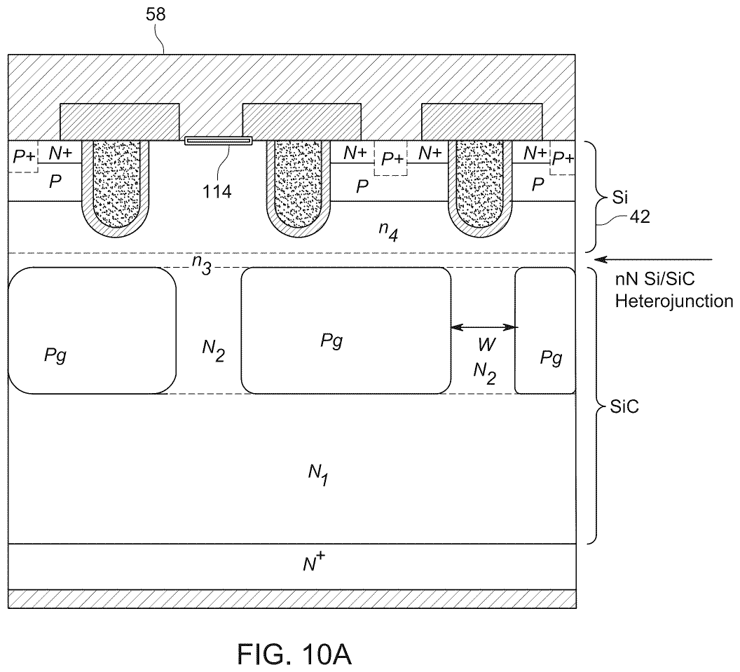

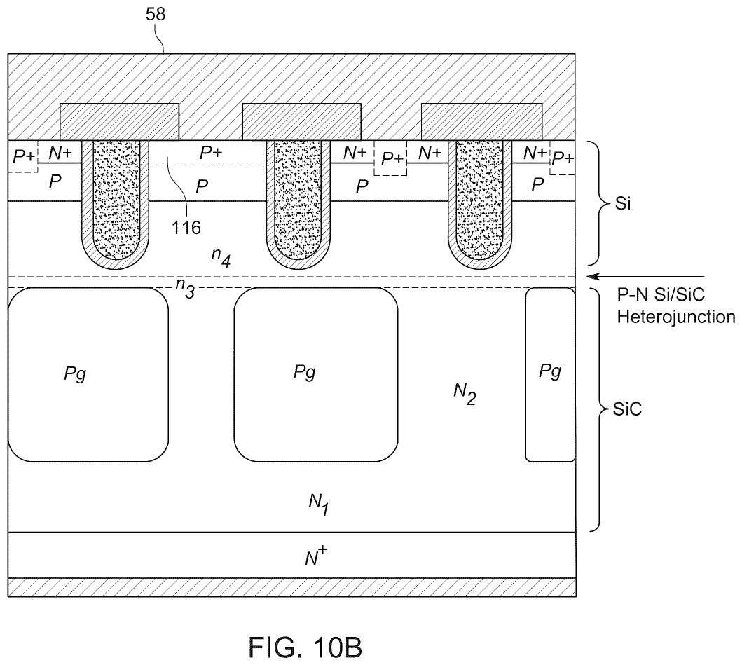

FIG. 10a shows the addition of a Schottky diode anode metal 114 between the source metal 58 and the N-type Si layer 42 to form a Schottky diode in parallel with the MOSFET. Under a reverse recovery condition, the Schottky diode conducts with a lower forward voltage drop than the PN diode formed by the P-well and n epi layer. The metal 114 may be aluminum.

FIG. 10b is similar to FIG. 10a but the diode is formed with a P+ region 116 to form a PN diode in parallel with the trench MOSFET.

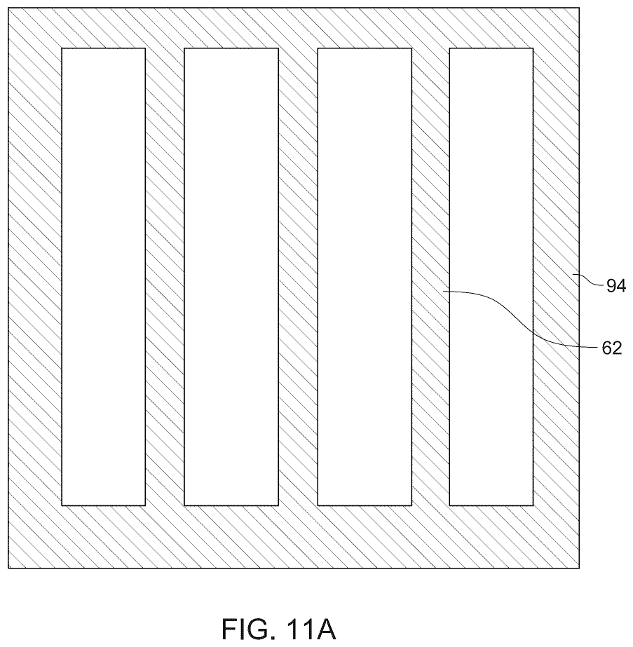

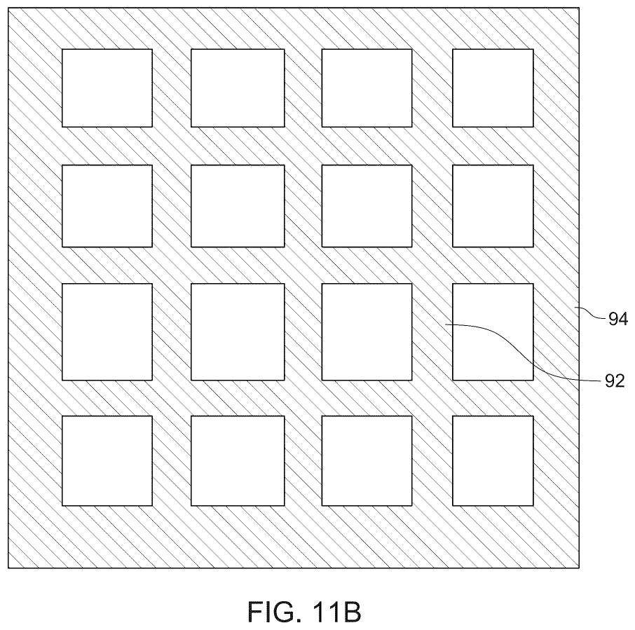

FIG. 11a illustrates a top-down view of four strips of cells (containing gate trenches) surrounded by the deep P+ contact region 94 of FIG. 6a (for shorting the JFET gates 62 to the source metal 58) and showing locations of the JFET gates 62 between the strips of gate trenches.

FIG. 11b illustrates a top-down view of 16 rectangular cells (containing gate trenches) surrounded by the deep P+ contact region 94 of FIG. 6a (for shorting the JFET gates 62 to the source metal 58) and showing locations of the JFET gates 62 between the rectangular gate trenches. The contact region 94 in FIGS. 11a and 11b may instead be the metal connector of FIG. 8.

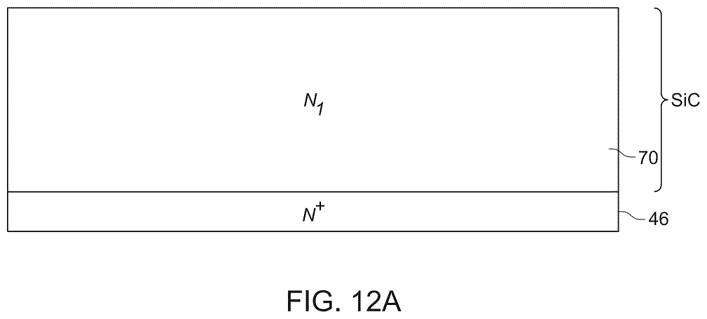

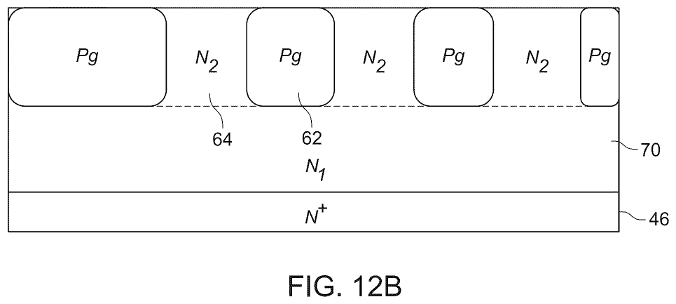

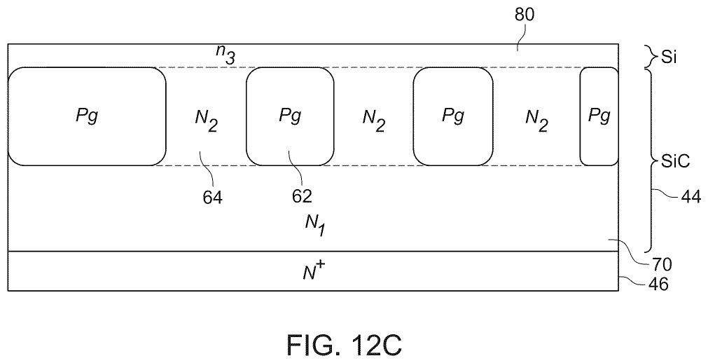

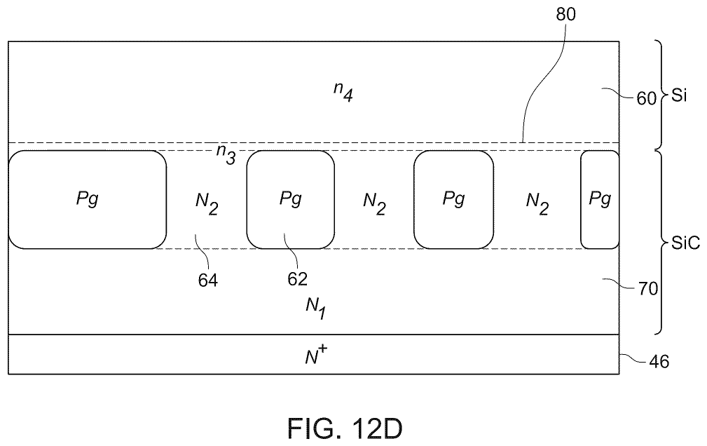

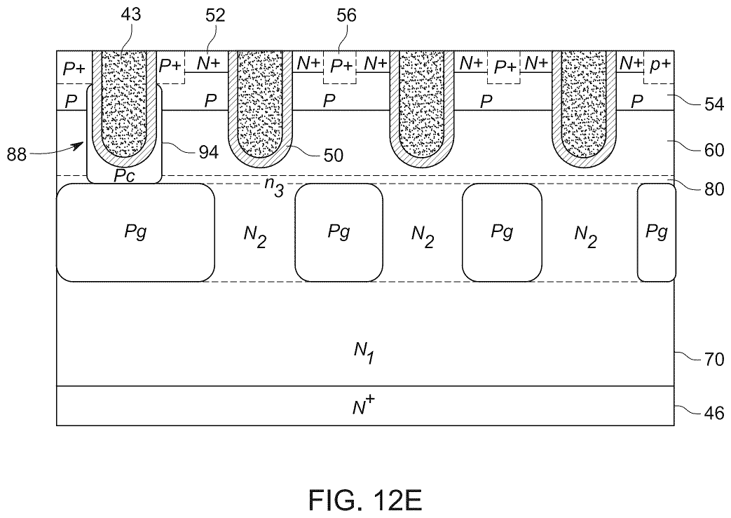

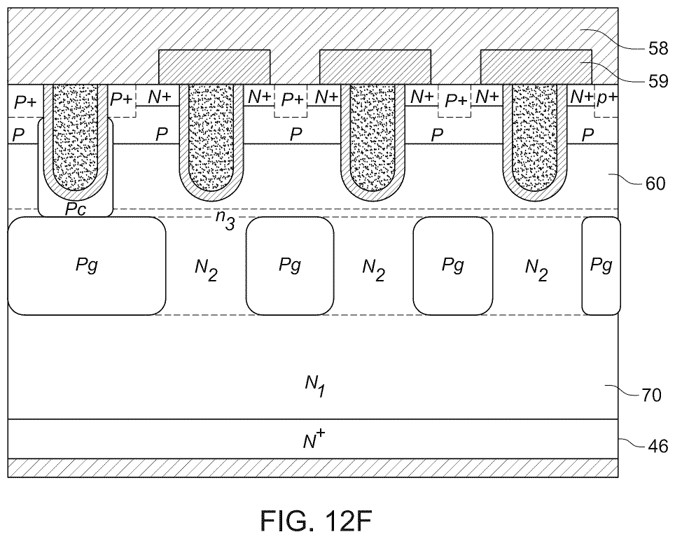

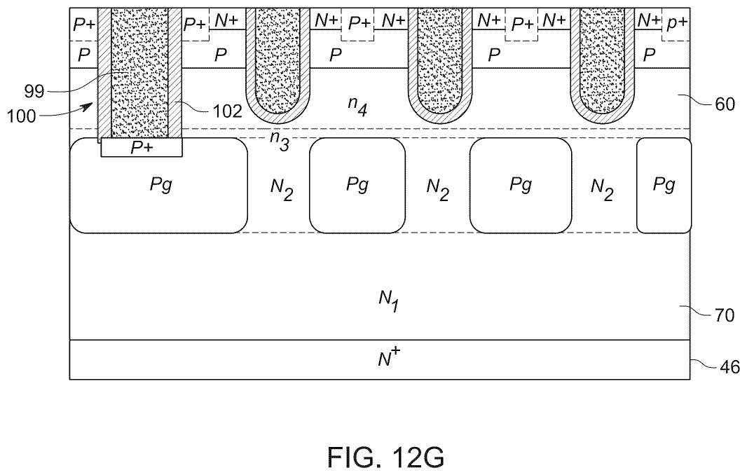

FIGS. 12a-12g illustrate process steps for forming the MOSFET embodiments of FIG. 7 or FIG. 8, which are easily adaptable to forming any of the other embodiments.

FIGS. 12a-12f show an example of a fabrication method to manufacture the MOSFET shown in FIG. 7.

FIG. 12a shows an N-type epitaxial SiC layer (drift region 70) epitaxially grown on a SiC N+ substrate 46. The substrate 46 can be a heavily N-type doped Si, SiC, or PolySiC wafer. The drift region 70 has a relatively low N-type dopant concentration of N1.

In FIG. 12b, a JFET channel layer, forming JFET channels 64, is formed by ion implantation, having an N-type dopant concentration of N2, which is selected to obtain the desired properties of the JFET. P-type dopants are also implanted in the JFET channel layer to form the JFET gates 62. The implanted dopants are annealed to activate them.

Alternatively, the JFET channel layer is formed using epitaxial growth techniques.

In FIG. 12c, a Si layer with a Si—SiC interface region 80 is formed on top of the SiC layer 44 by direct wafer bonding, or heteroepitaxially grown on the face of the SiC layer 44, or using MBE techniques. The interface region 80 of the heterojunction is heavily doped by doping the surfaces of the SiC and Si materials with an N-type material such as Phosphorus.

In FIG. 12d, a Si N-type epitaxial layer (bottom portion 60) is formed.

In FIG. 12e, known process steps are used to etch trenches, selectively implant P-type dopants in the leftmost trench 88 to create the P+ contact region 94, fill the trenches with doped polysilicon (to form the gate electrodes 43), form the gate oxide 50, form the P-well 54 using ion implantation, form the N+ source regions 52 using ion implantation, and form the P+ contact regions 56 using ion implantation.

In FIG. 12f, the top dielectric 59 is formed, and the source metal 58 and drain metal 68 are deposited. The bottom of the substrate 46 may be ground down before depositing the drain metal 68.

Alternatively, as shown in FIG. 12g, a different process is used to form the leftmost trench 100, deposit conductive material 99 in the trench 100, and form the dielectric 102 to fabricate the structure shown in FIG. 8.

Other structure variations, such as conventional split-gates in the gate trenches to reduce the gate drain charge, can also be implemented.

The specific electrical characteristics of devices fabricated using the methods described in this disclosure depend on several factors including the thickness of the layers, their doping levels, the materials being used, the geometry of the layout, etc. One of ordinary skill in the art will realize that simulation, experimentation, or a combination thereof can be used to determine the design parameters needed to operate as intended.

While the figures shown in this disclosure are not to scale but are qualitatively correct, the geometries used in practice may differ and should not be considered a limitation in any way. It is understood by those of ordinary skill in the art that the actual layout will vary depending on the specifics of the implementation and any depictions illustrated herein should not be considered a limitation in any way.

It is also understood that numerous combinations of the above embodiments can be realized. All the above variants of the structure can be realized in stripe or cellular layout such as square, rectangular, hexagonal or circular layouts.

The dopant types can be reversed for a P-channel MOSFET.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A vertical MOSFET comprising:
a substrate having a first conductivity type;
an epitaxially grown first layer grown over the substrate, the first layer having the first conductivity, the first layer being of a first semiconductor material having a first bandgap;
a second layer of the first conductivity type over the first layer, the second layer being of a second semiconductor material having a second bandgap that is narrower than the first bandgap, an interface of the first layer and the second layer forming a heterojunction of the first conductivity type;
a first region of a second conductivity type formed over the second layer and being of the second semiconductor material;
a second region of the first conductivity type formed over the first region to create a source region and being of the second semiconductor material;
a gate electrode insulated from the first region and configured to create an inversion layer in the first region when electrically biased above a threshold voltage to create a conductive path between the source region and the substrate;
a source electrode contacting the source region; and
a drain electrode contacting the substrate.

2. The MOSFET of claim 1 wherein the first semiconductor material is silicon carbide (SIC).

3. The MOSFET of claim 1 wherein the second semiconductor material is silicon (Si).

4. The MOSFET of claim 1 wherein the first semiconductor material is silicon carbide (SiC) and the second semiconductor material is silicon (Si).

5. The MOSFET of claim 4 wherein the first region forms a well layer.

6. The MOSFET of claim 4 wherein the first region is a body region.

7. The MOSFET of claim 1 wherein the first region forms a well layer and wherein the gate electrode is formed in an insulated trench in the second layer, where the trench is at least partially filled with a conductive material.

8. The MOSFET of claim 1 wherein the first region forms a body region and wherein the gate electrode is a planar gate electrode insulated from the body region.

9. The MOSFET of claim 1 further comprising a JFET layer in the first layer, the JFET layer comprising:
JFET gate regions of the second conductivity type and JFET channel regions of the first conductivity type; and
an electrical connector electrically connecting the source electrode to the JFET gate regions;
wherein the JFET channel regions are configured for conducting a vertical current when the MOSFET is in an on state.

10. The MOSFET of claim 9 where the first region forms a well layer and wherein the gate electrode is formed in an insulated first trench in the second layer, where the first trench is at least partially filled with a conductive material, wherein the electrical connector comprises a semiconductor contact region of the second conductivity type electrically connecting the source electrode to the JFET gate regions.

11. The MOSFET of claim 10 wherein the contact region surrounds a second trench that that does not contain the gate electrode.

12. The MOSFET of claim 11 wherein the second trench is filled with the conductive material.

13. The MOSFET of claim 9 where the first region forms a well layer and wherein the gate electrode is formed in an insulated first trench in the second layer, where the first trench is at least partially filled with a conductive material, wherein the electrical connector comprises a metal within a second trench that electrically connects the source electrode to the JFET gate regions.

14. The MOSFET of claim 9 where the first region forms a well layer and wherein the gate electrode is formed in an insulated first trench in the second layer, wherein the electrical connector is formed in a second trench that does not contain the gate electrode.

15. The MOSFET of claim 14 wherein the second trench is deeper than the first trench.

16. The MOSFET of claim 14 wherein the JFET gate regions form a grid, and a plurality of the gate electrodes are formed in openings in the grid.

17. The MOSFET of claim 1 further comprising a third layer of the first conductivity type, the third layer forming an interface layer between the first layer and the second layer, the third layer having a first conductivity dopant concentration higher than a dopant concentration of the first layer and the second layer.

18. The MOSFET of claim 1 wherein the second layer is epitaxially grown over the first layer.

19. The MOSFET of claim 1 wherein the second layer is bonded to the first layer.

20. A method for forming a vertical MOSFET comprising:
providing a substrate having a first conductivity type;
epitaxially growing a first layer over the substrate, the first layer having the first conductivity, the first layer being of a first semiconductor material having a first bandgap, the first layer comprising SiC;
providing a second layer of the first conductivity type over the first layer, the second layer being of a second semiconductor material having a second bandgap that is narrower than the first bandgap, the second layer comprising Si, an interface of the first layer and the second layer forming a heterojunction of the first conductivity type;
forming a first region of a second conductivity type formed over the second layer and being of the second semiconductor material;
forming a second region of the first conductivity type formed over the first region to create a source region and being of the second semiconductor material;
forming a gate electrode insulated from the first region and configured to create an inversion layer in the first region when electrically biased above a threshold voltage to create a conductive path between the source region and the substrate;
forming a source electrode contacting the source region; and
forming a drain electrode contacting the substrate.
